(19) United States
(12) Patent Application Publication
(10) Pub. No.: US 2007/0148870 A1
(43) Pub. Date: Jun. 28, 2007

(54) Method for forming common source line in NOR-type flash memory device

(75) Inventor: Hyun Soo Shin, Eumseong-gun (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu Electronics Co., Ltd.

(21) Appl. No.: 11/646,091

(22) Filed: Dec. 26, 2006

(30) Foreign Application Priority Data
Dec. 28, 2005 (KR) 10-2005-0131470

(51) Int. Cl. H01L 21/336

(52) U.S. Cl. 438/257

(57) ABSTRACT

Disclosed is a method for forming a common source line of a NOR-type flash memory. The method includes the steps of forming a photoresist pattern, which is used for exposing a common source area, on a plurality of stack gates formed on a semiconductor substrate, selectively etching a field oxide layer, which is previously formed in the common source area, by using the photoresist pattern as a mask, forming an amorphous layer on sidewalls of the stack gate patterns, and forming a common source line by implanting dopants into the common source area.

This application claims the benefit of Korean Application No 10-2005-0131470, filed on Dec. 28, 2005, which is incorporated by reference herein in its entirety.

### BACKGROUND OF THE INVENTION

1. Field of the Invention

The present invention relates to a method for manufacturing a semiconductor manufacturing technology. More specifically, the present invention relates to a method for forming a common source line in a NOR-type flash memory including a stack gate.

2. Description of the Related Art

A flash memory is a kind of PROM (programmable ROM) capable of electrically re-writing data. The flash memory can realize a program input scheme of an erasable PROM (EPROM) and an erase scheme of an electrically erasable PROM (EEPROM) using one transistor by combining the advantages of an EPROM, in which a memory cell includes one transistor so that a cell area is small, however, data must be erased at a time by UV rays, and the EEPROM, in which data can be electrically erased, however, a cell includes two transistors so that a cell area becomes large. The correct name of the flash memory is a flash EEPROM. The flash memory is referred to as a nonvolatile memory since stored information is not erased although power is turned off, which is different from a dynamic RAM (DRAM) or a static RAM (SRAM).

The flash memory is divided into a NOR-type structure in which cells are arranged in a row between a bit line and a ground and a NAND-type structure in which cells are arranged in series between the bit line and the ground. Since the NOR-type flash memory having the parallel structure can perform high speed random access when a reading operation is perform, the NOR-type flash memory is widely used for booting a mobile telephone. The NAND-type flash memory having the serial structure has low reading speed but high writing speed so that the NAND-type flash memory is suitable for storing data and is advantageous for miniaturization.

The flash memory is divided into a stack gate type and a split gate type in accordance with the structure of a unit cell and can be divided into a floating gate device and a silicon-oxide-nitride-oxide-silicon (SONOS) device in accordance with the shape of a charge storage layer. Among them, the floating gate device includes floating gates including polycrystalline silicon and being surrounded by an insulating substance. Charges are implanted into or discharged from the floating gates by channel hot carrier injection or Fowler-Nordheim (F-N) tunneling so that data can be stored and erased.

Meanwhile, in the procedure of manufacturing the NOR-type flash memory device, a cell threshold voltage is adjusted, and a stack gate including a floating gate, an inter-gate insulating layer (e.g., Oxide-Nitride-Oxide) and a control gate is formed. In addition, a common source line is formed through a self-aligned source (SAS) process. The SAS technique is used for reducing a cell size in a word-line direction. According to SAS technique, a common source line is formed through a dopant implantation process after etching a field oxide layer on the basis of etching selectivity among a polysilicon layer for a gate electrode, a silicon substrate, and a field oxide layer.

Hereinafter, a conventional SAS process will be briefly described with reference to FIGS. 1A and 1B. After forming a stack gate 20 including a tunnel oxide layer 22, a floating gate 24, an inter-gate dielectric layer 26, and a control gate 28, the SAS process is performed. Through the SAS process, after simultaneously opening source areas for 8-bit to 16-bit cells, an oxide layer (that is, a field oxide layer formed through shallow trench isolation (STI)) formed on an isolation area is removed. Accordingly, as shown in FIG. 1A, a common source area, that is, an area exposed between the stack gates 20 to form a common source line is formed with a trench 14 in a semiconductor substrate 10. Then, as shown in FIG. 1B, dopants (As or P) are implanted onto a surface of the exposed substrate, thereby forming an ion-implanted layer. The ion-implanted layer becomes a common source line 10L so as to electrically connect source diffusion areas of cells to each other.

Meanwhile, according to the SAS process, after performing an SAS etching process to selectively remove an STI insulating layer, a dopant implantation process is performed in order to form the common source line 10L. At this time, the dopants may be implanted even onto sidewalls (an area A of FIG. 1B) of the floating gate 24, the inter-gate dielectric layer 26, and the control gate 28 forming the stack gate 20. The implantation of dopants into the exposed area A may exert an influence on capacitance between the floating gate 24 and the control gate 26. For this reason, a coupling ratio is reduced, so the performance of the semiconductor device may be degraded.

Further, the flash memory device stores electrons in the floating gate of a cell area, and the stored electrons must be maintained for a long time. Accordingly, the damage of the stack gate must be prevented. However, according to the SAS process, the gate stack is damaged during the etching process and the ion implantation process. In other words, a word line stress occurs. Accordingly, if the flash memory is manufactured with the damage of the stack gate, a life span of a product may be shortened.

### SUMMARY OF THE INVENTION

The present invention has been made to solve the above problem occurring in the prior art, and therefore, it is an object of the present invention to provide a method for manufacturing a semiconductor device, capable of effectively preventing the change of capacitance between a floating gate and a control gate caused by the implantation of dopants onto sidewalls of a stack gate during an SAS process for forming a common source line of a NOR-type flash memory device.

In order to accomplish the object, there is provided to a method for forming a common source line of a NOR-type flash memory, including the steps of forming a photoresist pattern, which is used for exposing a common source area, on a plurality of stack gates formed on a semiconductor substrate, selectively etching a field oxide layer, which is previously formed in the common source area, by using the photoresist pattern as a mask, forming an amorphous layer on sidewalls of the stack gate patterns, and forming a common source line by implanting dopants into the common source area.

The stack gate pattern includes a tunnel oxide layer, a plurality of floating gates separated from each other by a predetermined interval, an inter-gate dielectric layer surrounding upper parts and sidewalls of the floating gates, and a control gate formed on the inter-gate dielectric layer. The step of selectively removing the field oxide layer is performed through a self-aligned source (SAS) etching process. The amorphous layer is formed by implanting dopants having a number of valence electrons identical to a number of valance electrons of a material forming the semiconductor substrate. The dopant includes germanium (Ge). The germanium is implanted with ion implantation energy of 1 KeV to 100 KeV and dose of 1E+12 ions/cm² to 1E+16 ions/cm² at an ion implantation angle in a range of 0° to 70° relative to a line perpendicular to a surface of the semiconductor substrate.

According to another aspect of the present invention, there is provided to a NOR-type flash memory device including a stack gate, which has, a floating gate storing electric charges, a control gate receiving driving power and an inter-gate dielectric layer interposed between the control gate and the floating gate, and a plurality of memory cells connected to each other by a common source line formed through a self-aligned source (SAS) in a row, the NOR-type flash memory comprises an amorphous layer formed on sidewalls of the stack gate according to the common source line. The amorphous layer is formed by implanting dopants onto the sidewalls of the stack gate. The dopant includes an element having a number of valence electrons identical to a number of valance electrons of a material forming a semiconductor substrate formed with the common source line. The semiconductor substrate includes a silicon substrate, and the dopant includes a germanium (Ge) ion.

### BRIEF DESCRIPTION OF THE DRAWINGS

FIGS. 1A and 1B are sectional views showing a conventional a self-aligned source (SAS) process; and

FIGS. 2 and 3 are sectional views sequentially showing processes of forming a common source line of a NOR-type flash memory device according to the present invention.

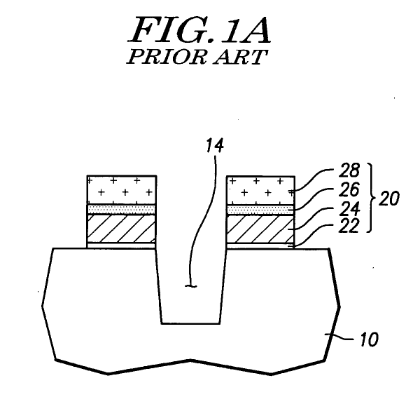

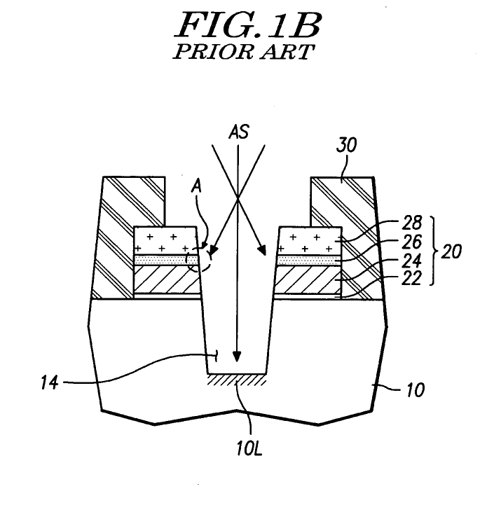

### DETAILED DESCRIPTION OF THE INVENTION

Hereinafter, a method for forming a common source line of a NOR-type flash memory device according to various preferred embodiments of the present invention will be described with reference to accompanying drawings.

A field oxide layer (not shown) or an isolation layer for defining an active device area, in which a memory cell is formed in a bit line direction, is formed on a silicon substrate 10 in which a flash memory device is formed later. In addition, on the active device area, a tunnel oxide layer 22 and a floating gate 24 are individually formed in each unit cell, and an ONO dielectric layer 26 covering the sidewalls and the upper part of the floating gate 24 and a control gate 28 receiving driving power are sequentially formed in a word-line direction.

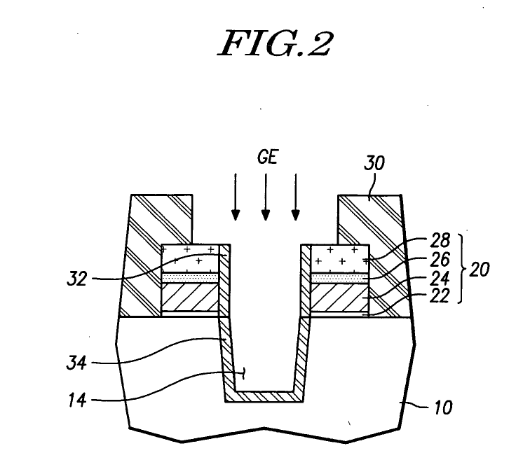

The tunnel oxide layer 22, the floating gate 24, the ONO dielectric layer 26, and the control gate 28 constitute one stack gate pattern 20. As shown in FIG. 2, several stack gate patterns are formed at a predetermined interval in a bit-line direction of the memory device. An area (a common source area), in which a common source line is formed, is exposed between neighboring stack gate patterns 20. At this time, the common source area has a structure in which the active device area and the field oxide layer are alternately repeated in a direction parallel to the word-line direction.

A photoresist pattern 30 which exposes the common source area is formed on an entire surface of the substrate 10 formed with the stack gate 20. Then, the oxide layer formed in a field area is removed by using the photoresist pattern 30 as an etching mask. If the field oxide layer is removed, a trench 14 is formed in the common source area as shown in FIG. 2. The field oxide layer may be selectively removed through the SAS etching process for selectively removing a field oxide layer by using etching selectivity among a polysilicon layer for a gate electrode, a silicon substrate, and a field oxide layer.

Then, dopants are implanted onto two sidewalls of the stack gates 20 opposite to each other by a predetermined depth by using the photoresist pattern 30 as a mask. If the dopants are implanted onto the sidewalls of the stack gates 20, the bond between elements forming a crystal lattice in the dopant-implanted area is broken, so the amorphous structure is achieved. Accordingly, an amorphous layer 32 is formed in the vicinity of the sidewalls of the stack gates. It is preferred that the dopants are elements (IV-group elements in a periodic table) having the same number of valence electrons as that of a material (i.e., silicon) forming the substrate. In other words, only when dopants having the same number of valence electrons as that of a material (i.e., silicon) forming the substrate are implanted, there is no influence on charge balance of a source diffusion area to be formed in the following process.

The amorphous layer 32 formed at the sidewalls of the stack gate 20 prevents the dopants (As or P) from deeply being implanted into the stack gate during a dopant implantation process for forming the common source line. In other words, most dopants implanted to form the common source line are detained in the amorphous layers 32 and 34, so that the dopants may not deeply penetrate into the inner part of the stack gate 20. Accordingly, although dopants are inevitably implanted into the stack gate during the dopant implantation process, it is possible to minimize the influence on capacitance between the floating gate 24 and the control gate 28 caused by the dopant implantation.

Meanwhile, according to an embodiment of the present invention, germanium (Ge) is used as dopants forming the amorphous layers 32, and the germanium is implanted with ion implantation energy of 1 KeV to 100 KeV and dose of 1E+12 ions/cm² to 1E+16 ions/cm². In this case, the germanium is implanted even onto the surface of the substrate 10 corresponding to the common source area, so the amorphous layer 34 including amorphous silicon may be formed. However, although the amorphous layer 34 is formed on the substrate 10, this does not exert an influence upon the following process of forming the common source line. However, preferably, in order to effectively prevent the amorphous layer 34 from being formed on the common source line, that is, in order to minimize the implantation of dopants into the surface of the substrate 10, an ion implanting angle must be adjusted. The ion implantation angle may be adjusted in the range of 0° to 70° relative to a line perpendicular to the surface of the substrate 10.

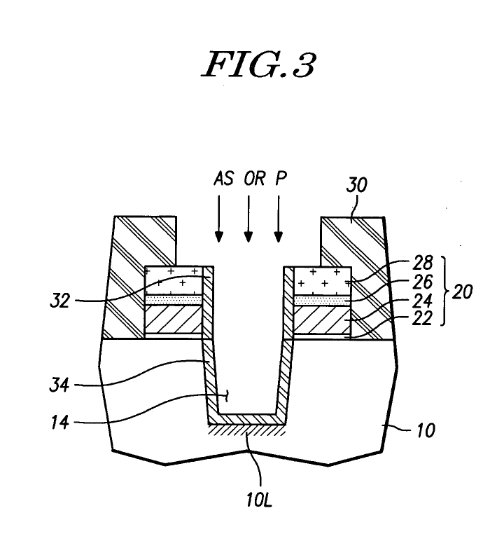

As shown in FIG. 3, after forming the amorphous layers 32, a typical SAS ion implantation process is performed. The implanted dopants include arsenic (As) or phosphorous (P). Thus, the common source line 10L connecting a plurality of memory cells to each other in a row is formed. Meanwhile, although the amorphous layer 34 may be formed on the surface of the substrate corresponding to the common source area through the process of forming an amorphous layer, the amorphous layer 34 does not exert an influence on the process of forming the common source line.

As described above, according to the present invention, dopants implanted in order to form a common source line are deeply implanted onto sidewalls of a stack gate, so that it is possible to prevent the influence on capacitance between a floating gate and a control gate forming a memory cell.

In addition, according to the present invention, it is possible to remarkably reduce word line stress occurring due to dopant implantation.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for forming a common source line in a non-volatile memory, the method comprising the steps of:
forming a photoresist pattern on a plurality of nonvolatile transistor gates on a semiconductor substrate, exposing a common source area;
etching a field oxide layer in the common source area using the photoresist pattern as a mask;
forming an amorphous layer on sidewalls of the nonvolatile transistor gates; and
forming a common source line by implanting a first dopant into the common source area.

2. The method as claimed in claim 1, wherein the nonvolatile transistor gates include:
a tunnel oxide layer;
a plurality of floating gates a predetermined interval apart from each other;
an inter-gate dielectric layer on a upper part of the floating gates; and
a control gate on the inter-gate dielectric layer.

3. The method as claimed in claim 1, wherein the step of selectively removing the field oxide layer comprises a self-aligned source (SAS) etching process.

4. The method as claimed in claim 1, wherein forming the amorphous layer comprises implanting a second dopant having a number of valence electrons identical to a number of valance electrons of a material in the semiconductor substrate.

5. The method as claimed in claim 4, wherein the second dopant includes germanium (Ge).

6. The method as claimed in claim 4, wherein the second dopant includes silicon (Si).

7. The method as claimed in claim 5, wherein the germanium is implanted at an ion implantation energy of 1 KeV to 100 KeV.

8. The method as claimed in claim 5, wherein the germanium is implanted at a dose of 1E+12 ions/cm² to 1E+16 ions/cm².

9. The method as claimed in claim 5, wherein the germanium is implanted at an ion implantation angle in a range of from 0° to 70° relative to a line perpendicular to a surface of the semiconductor substrate.

10. The method as claimed in claim 5, wherein the intergate dielectric is also on sidewalls of the floating gate.

11. The method as claimed in claim 1, wherein the first dopant includes boron (B), arsenic (As), or phosphorous (P).

12. The method as claimed in claim 11, wherein the first dopant includes As or P.

13. The method as claimed in claim 11, wherein the first dopant is implanted under conditions effective to prevent most of the first dopant from penetrating through the amorphous layer.

14. A nonvolatile memory device including a plurality of nonvolatile memory cells, each having a floating gate storing electric charges, a control gate receiving power and an inter-gate dielectric layer between the control gate and the floating gate, the plurality of nonvolatile memory cells being connected to each other by a common self-aligned source (SAS), further comprising an amorphous layer on sidewalls of the nonvolatile memory cells adjacent to the common source line.

15. The nonvolatile memory device as claimed in claim 14, wherein the amorphous layer comprises a dopant-implanted surface layer.

16. The nonvolatile memory device as claimed in claim 14, wherein the amorphous layer comprises a surface layer of the nonvolatile memory cells having a dopant therein.

17. The nonvolatile memory device as claimed in claim 16, wherein the dopant includes an element having a number of valence electrons identical to a number of valance electrons of a material in a semiconductor substrate including the common self-aligned source.

18. The nonvolatile memory device as claimed in claim 17, wherein the semiconductor substrate includes a silicon substrate, and the dopant includes a germanium (Ge).

19. The nonvolatile memory device as claimed in claim 14, wherein the nonvolatile memory device is a NOR-type flash memory.

20. The nonvolatile memory device as claimed in claim 14, wherein the intergate dielectric is also on sidewalls of the floating gate.
